(19) United States
(12) Patent Application Publication
(10) Pub. No.: US 2026/0204328 A1
(43) Pub. Date: Jul. 16, 2026

(54) BOUNDARY OFFSET CONTROL FOR MEMORY BLOCK READING

(71) Applicant: Micron Technology, Inc., Boise, ID (US)

(72) Inventors: Christina Papagianni, San Jose, CA (US); Murong Lang, San Jose, CA (US); Yang Liu, Melissa, TX (US); Yueh-hung Chen, Sunnyvale, CA (US)

(21) Appl. No.: 19/020,524

(22) Filed: Jan. 14, 2025

(51) Int. Cl. G11C 16/34; G11C 8/12; G11C 11/06; G11C 11/065; G11C 11/408; G11C 16/08; G11C 16/10; G11C 16/26

(52) U.S. Cl. CPC G11C 16/3427; G11C 8/12; G11C 11/06042; G11C 11/06071; G11C 11/065; G11C 11/4087; G11C 16/08; G11C 16/102; G11C 16/26; G11C 2211/5646

(57) ABSTRACT

A system and method are provided for reading data from a memory device. The system and method receive a request to read data from a portion of a memory device. The system and method, in response to receiving the request to read the data, determine whether the portion of the memory device is available for writing data. The system and method selectively apply boundary word line (WL) offset values to read one or more WLs of the portion of the memory device in addition to applying inner WL offset values in response to determining whether the portion of the memory device is available for writing data.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 is a block diagram of example inner and boundary word line (WL) read level offset tables, in accordance with some examples.

FIG. 3 is a block diagram of an example of applying an adjusted boundary WL read level offset to read data from a WL, in accordance with some examples.

FIG. 4 illustrates a diagram of operations performed using the media operations manager, in accordance with some examples.

FIG. 5 is a block diagram of an example computer system, in accordance with some examples.

### DETAILED DESCRIPTION

The present disclosure configures a memory sub-system controller to perform selection of read level offsets when reading data from a memory device based on whether a block is open or closed. Specifically, when reading a portion of the memory device, the controller determines whether the block is available for writing (open) or unavailable for writing (closed). For open blocks, the controller applies only inner wordline (WL) offset values without boundary WL offsets to prevent over-compensation issues that can occur due to delays in updating last written page (LWP) information. For closed blocks that are partially programmed, the controller applies both inner WL offsets and boundary WL offsets, where the boundary WL offsets are specifically applied to the last written WL. This selective application of offset values helps reduce trigger rate issues and maintains raw bit error rates (RBER) below hard decode limits, improving the overall efficiency and performance of the memory sub-system. The controller uses lookup tables optimized for different device identifiers and platforms to store the inner and boundary WL offset values. This approach particularly benefits data center solid state drives (SSDs) where blocks can remain open for up to one hour and where accurate compensation is important for maintaining read performance.

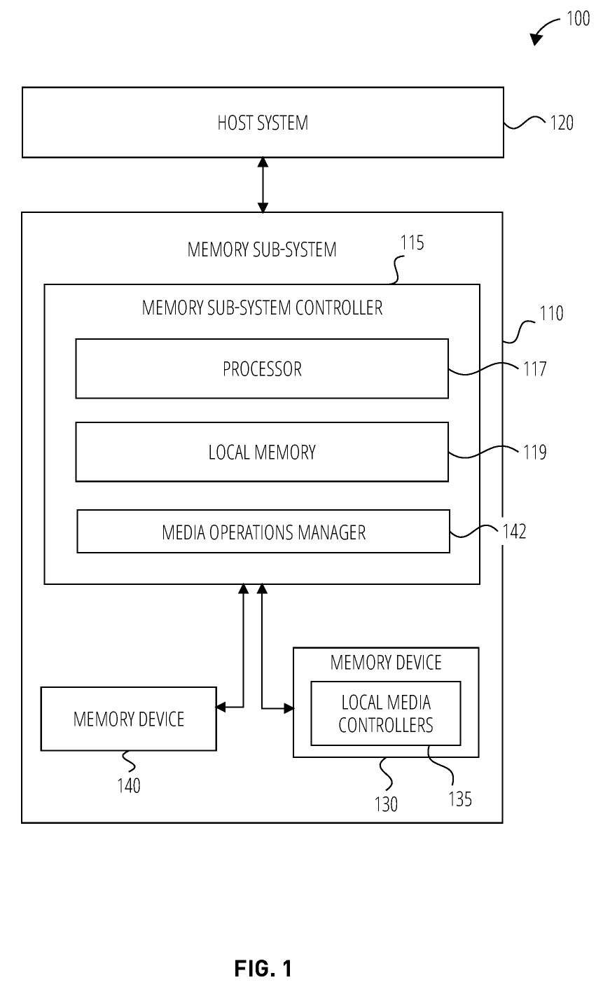

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as "garbage collection data". “User data” can include host data and garbage collection data. "System data" hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. Specifically, certain memory devices, such as NAND flash devices, store data in different WLs. The memory devices can program data into different blocks. Memory blocks that are fully programmed and are closed are referred to as full blocks (FBs). Memory blocks that are not fully programmed (can be referred to as partially programmed blocks (PBs)) which can exist in two states. The PB can be open blocks that remain available for writing. The PB can be closed blocks that are no longer available for writing even though they are not fully programmed. In data center SSDs, blocks can remain open for up to one hour before being closed, and when closed, these blocks are not padded with dummy data to fill the remaining space. Such blocks are PB and are closed preventing additional data from being written to the closed PB. In order to reduce read disturb errors and other extrinsic defect related errors when reading data, the controllers can apply offsets to the read threshold voltages used to read data from FBs and PBs.

In some cases, the controllers keep track of which regions of the memory components were last programmed. Namely, the controllers can store an indicator of the location of the last page that was programmed to the set of memory components. The WL that includes the last page that was programmed can be referred to as a boundary WL. All other WLs that do not include the last page can be referred to as inner WLs. Reading data from boundary WLs which correspond to a last written page (LWP) may involve adding additional read offset compensation from a boundary WL table.

Conventional memory sub-systems face challenges when managing read operations for PBs due to delays in updating LWP information. Specifically, in data center SSDs, the LWP update can lag by at least one second, during which time up to 38 additional pages may be written to an open block. This delay causes the system to incorrectly identify inner WLs as boundary WLs, resulting in over-compensation of read threshold voltages. For example, when the system incorrectly identifies the LWP being at WL3 when the actual LWP is at WL40, the controller may erroneously apply boundary offsets of -180 to -230mV to the data read from WL3 instead of the correct inner WL offsets of -50 to -60mV. This results in an RBER that may transgress a threshold thereby triggering data recovery operations.

This over-compensation issue can be particularly problematic in data center SSDs where blocks can remain open for up to one hour. The conventional approach of applying both inner and boundary WL offsets to all PBs on the assumption that the PBs have the LWP fails to account for the dynamic nature of open blocks. This can lead to trigger rate issues and degraded read performance. When inner WLs are incorrectly over-compensated with boundary offsets, the RBER approaches or exceeds the soft decode limit. The problem is compounded in data center SSDs because blocks can be closed before being fully programmed, and these blocks are not padded with dummy data. The conventional static offset approach cannot properly distinguish between open and closed PBs, leading to suboptimal read threshold voltage compensation that impacts system performance and reliability.

The present disclosure addresses these technical challenges in memory systems by providing a memory sub-system controller that selectively applies read level voltage offsets based on whether a block is open or closed. Specifically, for open blocks where the LWP information can lag by up to one second and allow 38 additional pages to be written, the memory controller applies only inner WL offsets without boundary WL offsets to prevent over-compensation issues. This approach can eliminate the possibility of incorrectly applying large boundary offsets (-180 to -230mV) when they should be using smaller inner offsets (-50 to -60mV). For closed memory blocks that are PB, the memory controller applies both inner WL offsets and boundary WL offsets, with the boundary WL offsets specifically applied to the last written WL. The memory controller can use optimized lookup tables that store different offset values based on the device identifier and platform, particularly benefiting data center SSDs where blocks can remain open for extended periods. Rather than risking trigger rate issues from over-compensation, this dynamic approach maintains RBER below hard decode limits while ensuring optimal read threshold voltage compensation. The memory sub-system can track block status through cursor information and other resources that indicate whether blocks are written or fully written, enabling accurate offset selection even when blocks are closed before being fully programmed. This selective application of offset values can improve read performance and reliability in data center SSDs where accurate compensation is important.

In some examples, a processing device coupled to a memory device can receive requests to read data from portions of the memory device. The processing device can determine whether memory portions are available for writing data and selectively applies different WL offset values based on this determination. In some cases, when the processing device determines a portion is available for writing data (an open block), the processing device applies only inner WL offset values without boundary WL offsets. Conversely, when a portion is unavailable for writing (a closed block), the processing device applies both inner WL offset values and boundary WL offsets.

In some circumstances, the processing device tracks writing progress within memory portions using cursor information and other resources to determine block status. For data center SSDs, blocks can remain open for up to one hour before transitioning to a closed state, and importantly, these blocks are not padded with dummy data when closed. In some examples, the memory portions contain multiple WLs, including inner WLs and boundary WLs. This is the case for PB that are open or closed. The processing device stores offset values in dedicated tables - an inner WL offset table for inner WL offsets and a boundary WL offset table for boundary WL offsets. For closed PB that are unavailable for writing new data, the processing device combines these offset values when reading boundary WL.

The processing device may retrieve a read threshold voltage and modify it using either inner WL offsets alone or a combination of inner and boundary WL offsets, depending on the block status. For closed blocks, the processing device generates a combined offset by adding the inner WL offset and boundary WL offset values. In some implementations, the offset tables are optimized for different device identifiers and platforms, particularly benefiting data center SSDs where accurate compensation is important. The processing device uses these tables to maintain RBERs below hard decode limits while preventing trigger rate issues that could arise from over-compensation.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

In some examples, the memory device 130, including one or more portions (e.g., one or more WLs, one or more WLGs, one or more blocks, one or more memory dies, and/or one or more pages) or group of memory components including the memory device 130, can be associated with a first reliability (capability) grade, value, measure, or lifetime PEC. The terms “reliability grade,” “value” and “measure” are used interchangeably throughout and can have the same meaning. The memory device 140 (e.g., one or more WLs, one or more WLGs, one or more blocks, one or more memory dies, and/or one or more pages) or group of memory components, including the memory device 140, can be associated with a second reliability (capability) grade, value, measure, or lifetime PEC. In some examples, each memory component (memory device 130 and memory device 140) can store respective configuration data that specifies the respective reliability grade and lifetime PEC and current PEC and/or other conditions discussed below. In some examples, a memory or register can be associated with all of the memory components (memory device 130 and memory device 140) and can store a table that maps different groups, portions, bins or sets of the memory device 130 and memory device 140 to respective reliability grades, conditions, lifetime PEC values, and/or current PEC values.

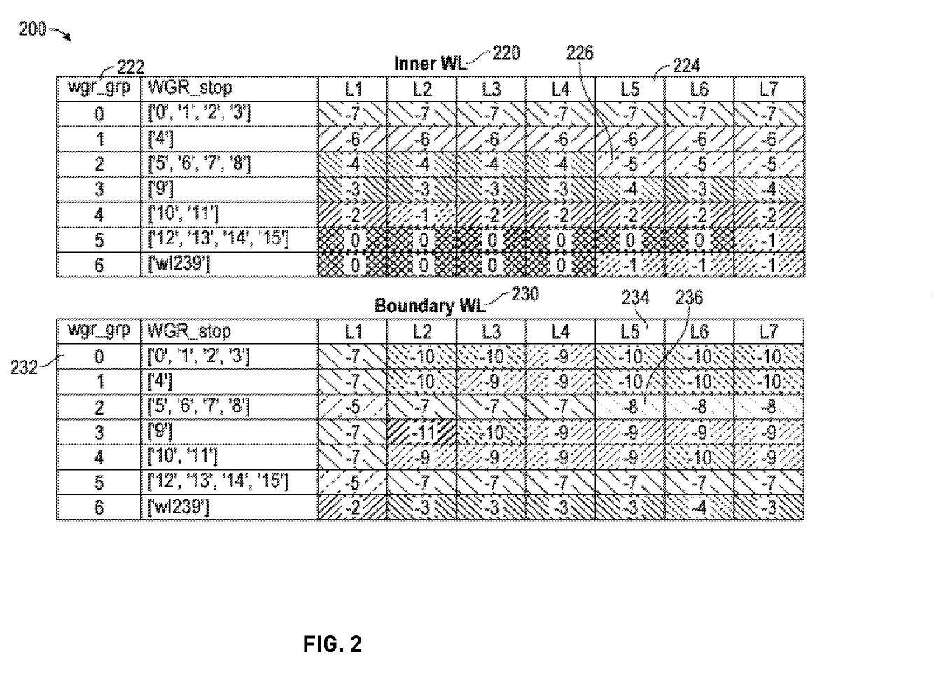

In some cases, a memory or register (e.g., included as part of the local memory 119) can store an inner WL offset table and a boundary WL offset table. In some cases, the inner WL offset table and the boundary WL offset table can be combined into a single table. For example, as shown in diagram 200 of FIG. 2, the inner WL offset table 220 can store various read level offsets that can be applied to a read threshold voltage when reading one or more inner WLs. Namely, a first WL or WLG 222 can be associated with a first set of read level offsets 224. Each read level offset in the first set of read level offsets 224 can represent a different amount of offset to apply to the read threshold voltage when reading different levels of TLC storage (or other multi-level cell storage). Namely, when reading level 1 from the TLC storage in a WL that is part of a first WLG (e.g., any WL specified by the WGR_stop for WGR_grp 4, and specifically WLG_stop ‘10’ or WLG_stop “11’), a -2 DAC offset can be applied, when reading level 2 from the TLC storage in the WL part of the first WLG, a -1 DAC offset can be applied, and when reading levels 3-7 from the TLC storage in WL that is part of the first WLG, a -2 DAC offset can be applied. The first column shown in FIG. 2 represents WLG grouping columns. The actual WLGs are defined in the second column WLG_stop. If any WL is in a given WLG_stop, it may use the specified read offsets for each level in that WLG. Any WL in WLG_stop 10 or WLG_stop 11 may have to use the offset corresponding to the WGR_GRP 4 group.

A second WL or WLG 222 can be associated with a second set of read level offsets 224. Each read level offset in the second set of read level offsets 224 can represent a different amount of offset to apply to the read threshold voltage when reading different levels of TLC storage. Namely, when reading levels 1-4 from the TLC storage in the second WLG (e.g., word line group 6), and when reading levels 5-7 from the TLC storage in the second WLG, a -1 DAC offset can be applied.

The boundary WL offset table 230 can store various read level offsets that can be applied to a read threshold voltage when reading one or more boundary WLs (e.g., WLs that include a last programmed portion or page or WL). Namely, the first WL or WLG 232 can be associated with a second set of read level offsets 234. Each read level offset in the third set of read level offsets 234 can represent a different amount of offset to apply to the read threshold voltage when reading different levels of TLC storage (or other multi-level cell storage). These offsets can be the same or different from those mentioned with respect to the inner WL offset table 220. For example, the read level offset 226 in the inner WL offset table 220 for a particular WL and for a particular level of the TLC storage can be a first value of -5 DAC. The read level offset 236 in the boundary WL offset table 230 for the same particular WL and for the same particular level of the TLC storage can be a second value of -8 DAC.

In some cases, the media operations manager 142 determines that the request to read the portion of the set of memory components corresponds to a PB (open or closed). In such cases, the media operations manager 142 can access a buffer or storage to identify which WL is indicated to store the last programmed portion or page. The media operations manager 142 can determine a level of the TLC storage that is being read and retrieves the read level offset stored in the inner WL offset table 220. The media operations manager 142 obtains a read threshold voltage for reading data from the portion and modifies the read threshold voltage by the read level offset retrieved from the inner WL offset table 220. The media operations manager 142 can then read each inner WL of the PB using the same modified read threshold voltage. Namely, the media operations manager 142 can read each WL of the PB excluding the identified WL that includes the last programmed portion or page using the read threshold voltage that has been modified by the corresponding value in the inner WL offset table 220. In some cases, if the PB is an open block, the media operations manager 142 applies the same inner WL offset to read portions of the open block including the inner WLs and the boundary WLs.

In response to determining that the PB is a closed block, the media operations manager 142 can obtain the read level offset stored in the boundary WL offset table 230 for the read level being read from the identified WL that includes the last programmed portion or page or last programmed WL. The media operations manager 142 can combine (e.g., add) the read level offset stored in the boundary WL offset table 230 with the read level offset that was used to read the inner WL to generate a second read level offset. In some cases, a table (a separate table) can be maintained that includes the already combined values so that the media operations manager 142 does not have to combine the read level offset stored in the boundary WL offset table 230 with the read level offset that was used to read the inner WL to generate the second read level offset (e.g., the second read level offset can be precomputed and stored in a table). The media operations manager 142 can then read the identified WL of the closed PB that includes the last programmed portion or page or last programmed WL using the read threshold voltage adjusted by the second read level offset.

Referring back to FIG. 1, a memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells (e.g., including multi-level cell storage), such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or block stripes (BSs). As used herein, a block comprising SLCs can be referred to as a SLC block, a block including MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

The media operations manager 142 can perform selection of read level offsets when reading data from a memory device 130 based on whether a block (or portion) is open or closed. Specifically, when reading a portion of the memory device 130, the media operations manager 142 can determine whether the block is available for writing (open) or unavailable for writing (closed). For open blocks, the media operations manager 142 applies only inner WL offset values without boundary WL offsets to prevent over-compensation issues that can occur due to delays in updating LWP information. For closed blocks that are partially programmed, the media operations manager 142 applies both inner WL offsets and boundary WL offsets, where the boundary WL offsets are specifically applied to the last written WL. This selective application of offset values helps reduce trigger rate issues and maintains RBER below hard decode limits, improving the overall efficiency and performance of the memory sub-system 110. The media operations manager 142 uses lookup tables optimized for different device identifiers and platforms to store the inner and boundary WL offset values. This approach particularly benefits data center SSDs where blocks can remain open for up to one hour and where accurate compensation is important for maintaining read performance.

Any discussion with respect to the memory device 130 can similarly be applied to the memory device 140. Any function pertaining to the local media controllers 135 can, in some cases, be performed by the device) memory sub-system controller 115.

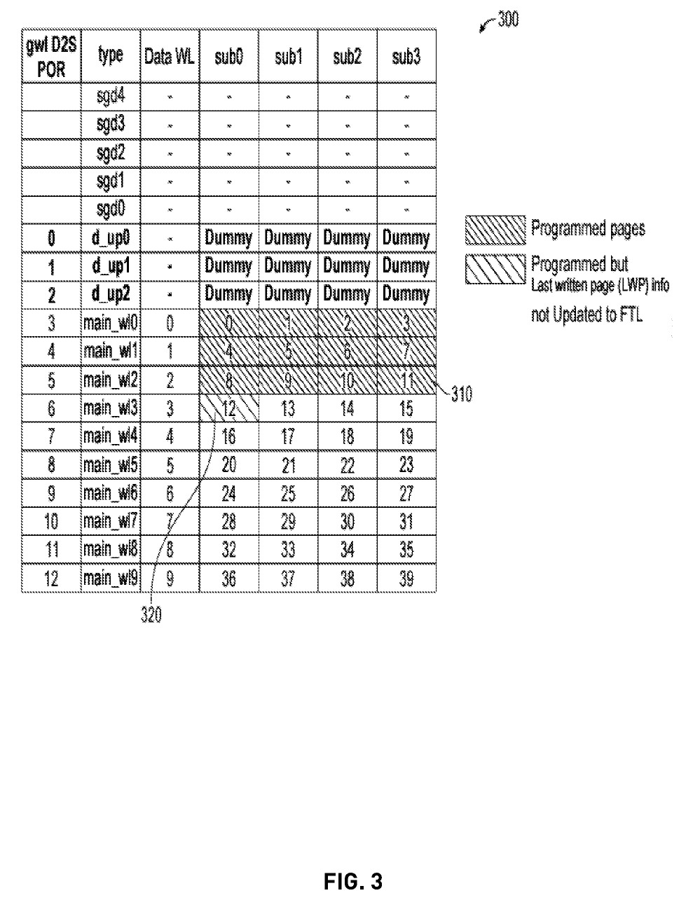

As shown in the diagram 300 of FIG. 3, the media operations manager 142 can store or program data sequentially across SBs of the memory device 130. The media operations manager 142 can maintain a pointer or buffer that identifies what the last programmed portion or page is in the memory device 130. Specifically, the media operations manager 142 can store a pointer indicating that the SB3 310 in WL5 is the last programmed portion or page or WL. This pointer or cursor is stored in association with each memory block including closed blocks and open blocks to enable the selective application of the boundary WL offsets to read data.

For example, when reading data from the WL5, the media operations manager 142 can determine that the WL5 is a closed PB that includes the last programmed portion or page or WL based on the data stored in the buffer or pointer. The media operations manager 142 can use the read level offset stored in the boundary WL offset table 230 together with the read level offset stored in the inner WL offset table 220 to read data from the WLG0 (WL5 is in WLG0).

In some implementations, the media operations manager 142 may receive requests to read data from portions (e.g., memory blocks) of the memory device 130. Upon receiving such requests, the media operations manager 142 determines whether the requested memory portion is available for writing data by checking block status information. Specifically, the media operations manager 142 may maintain tracking information through cursor mechanisms that indicate writing progress within memory blocks. This tracking enables the media operations manager 142 to accurately determine whether a memory block is open and available for writing or has been closed.

In some implementations, the media operations manager 142 may track block status through a cursor system that monitors writing progress. The cursor indicates whether a block has reached the end of available space, with blocks being considered open if they have not reached the end and closed once they have reached their endpoint. This cursor-based tracking provides a dynamic way to monitor the current state of each block without requiring additional storage overhead. Additionally, the media operations manager 142 may utilize other system resources beyond the cursor to determine block status. These resources maintain information about whether pages within blocks are written or fully written, ensuring the system never attempts to read empty pages. This comprehensive tracking approach enables accurate identification of block status even in cases where blocks are closed before being completely programmed, particularly in data center SSDs where blocks may transition from open to closed status after remaining open for extended periods.

In some implementations, the media operations manager 142 may maintain a lookup table that tracks the status of memory blocks. This table can store information indicating whether each block is open (available for writing) or closed (unavailable for writing). For data center SSDs where blocks can remain open for up to one hour before transitioning to a closed state, the table can be updated when blocks are closed, even if they are not fully programmed. The media operations manager 142 may utilize this table in conjunction with other resources that indicate whether pages are written or fully written. When the media operations manager 142 receives a read request, the media operations manager 142 can quickly reference this table to determine the block's status and apply the appropriate offset values - using only inner WL offsets (or no offset at all) for open blocks while applying both inner and boundary WL offsets for last written portions of closed blocks and inner WL offsets for inner WLs of the closed blocks. For example, when a block transitions from open to closed status after a predetermined time threshold (e.g., after one hour), the table can be updated to reflect this change in status. This tracking mechanism ensures the system can properly identify PBs that have been closed, enabling accurate offset selection even when blocks are not padded with dummy data upon closure.

In certain implementations, the media operations manager 142 applies different read voltage compensation strategies based on memory block status or state. For open blocks that remain available for writing, the media operations manager 142 deliberately applies only inner WL offset values while avoiding boundary WL offset values. The media operations manager 142 may store offset values in dedicated lookup tables (such as the inner WL offset table 220 and boundary WL offset table 230 of FIG. 2) optimized for different device types and platforms. These tables can include an inner WL offset table containing read level offsets for inner WLs and a boundary WLs offset table containing offsets specifically for boundary WLs.

When reading from closed memory blocks, the media operations manager 142 may apply a comprehensive compensation approach. For these memory blocks that are no longer available for writing, the media operations manager 142 applies both inner WL offsets and boundary WL offsets, particularly when reading the last written WL. The media operations manager 142 may determine block closure based on various conditions. In data center SSDs, memory blocks may transition from open to closed status after remaining open for up to one hour, and importantly, these memory blocks are not padded with dummy data when closed.

In some examples, to prevent over-compensation issues, the media operations manager 142 may implement careful offset selection for open blocks. This approach addresses challenges that arise from delays in updating LWP information, which can be as long as one second during which additional pages may be written. The media operations manager 142 may utilize system resources to track whether pages within blocks are partially written (e.g., are PB) or fully written (e.g., are FB). This tracking ensures accurate offset selection even when memory blocks are closed before being completely programmed.

For reading operations, the media operations manager 142 may retrieve base read threshold voltages and modify them according to the selected offset values. The modification depends on block status - using either inner WL offsets alone or combining them with boundary WL offsets as appropriate. For example, for reading operations in open memory blocks, the media operations manager 142 may retrieve base read threshold voltages and apply only inner WL offsets or no offsets at all. For example, when reading data that would require a -50 to -60mV compensation, the media operations manager 142 applies only these inner WL offset values without adding any boundary WL offsets. This approach prevents over-compensation issues that could arise from delays in updating last written page information.

In closed blocks that are PBs, the media operations manager 142 may implement a more comprehensive voltage modification approach. When reading the last written WL in these memory blocks, the media operations manager 142 combines both the inner WL offset and the boundary WL offset values. The media operations manager 142 retrieves these values from dedicated lookup tables that are optimized for different device types and platforms, ensuring appropriate compensation levels for each specific configuration. The media operations manager 142 may carefully calibrate these voltage modifications to maintain RBER below hard decode limits. For inner WLs in open memory blocks, the manager's selective application of only inner WL offsets helps prevent trigger rate issues that could arise from over-compensation. Even when using non-optimum offset values, this approach keeps the RBER below the hard decode limit while ensuring reliable data retrieval.

For boundary WLs in closed blocks, the media operations manager 142 may apply the combined offset values to properly compensate for various physical effects. These effects can include cell-to-cell coupling, back pattern effects, and lateral charge migration that particularly impact the last written WL. The media operations manager 142's careful selection and application of these offset values helps maintain optimal read performance while accounting for the unique characteristics of partially programmed blocks. Specifically, for closed blocks, the media operations manager 142 may apply different offset strategies depending on the WL location. When reading inner WL of closed blocks, the media operations manager 142 can apply only inner WL offset values to properly compensate for effects like cell-to-cell coupling and back pattern effects. For boundary WLs in closed blocks, the media operations manager 142 can apply a combined offset (e.g., by adding values of both inner WL and boundary WL offset values) to account for additional physical effects like lateral charge migration that particularly impact the last written WL. This selective application of offset values helps maintain optimal read performance - using inner offsets alone for inner WLs while applying the combined offsets only for the true boundary WL of PBs that have been closed.

The media operations manager 142 may maintain RBER below hard decode limits through careful offset selection. This management proves particularly important for data center SSDs where accurate compensation is critical for maintaining read performance. In some implementations, the media operations manager 142 may handle PBs that have been closed differently from open memory blocks. For these closed PBs, the media operations manager 142 can apply both types of offsets while ensuring proper identification of true boundary WL. The media operations manager 142 may prevent trigger rate issues by avoiding over-compensation of inner WL. This is achieved by eliminating the application of boundary WL offsets to open memory blocks where LWP information might be delayed. Through careful orchestration of offset values, the media operations manager 142 may ensure optimal read performance throughout the lifecycle of memory blocks, whether they are open for writing or have been closed in a partially programmed state.

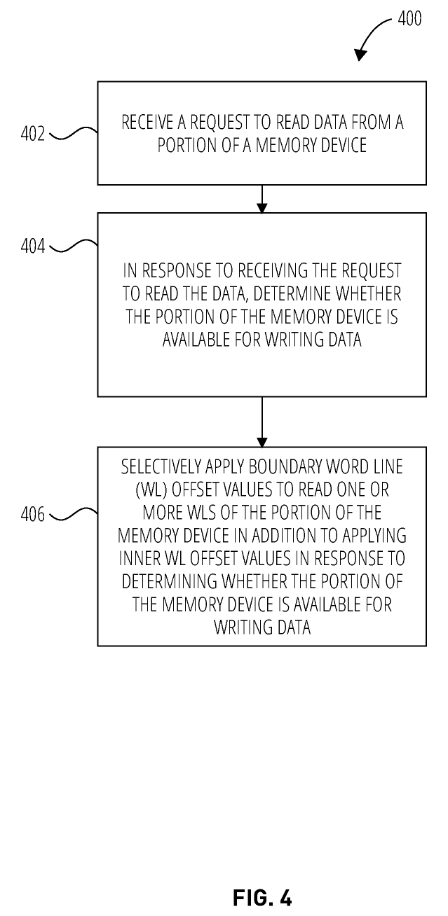

FIG. 4 illustrates a diagram 400 of operations performed using the media operations manager 142, in accordance with some examples. The method or process of diagram 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 400 is performed by the memory sub-system controller 115, local media controllers 135, and/or subcomponents of the memory sub-system controller 115 and/or local media controllers 135 of FIG. 1. In these examples, the method or process of diagram 400 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 4, the method begins at operation 402 with the media operations manager 142 receiving a request to read data from a portion of the memory device 130. At operation 404, the media operations manager 142, in response to receiving the request to read the data, determines whether the portion of the memory device 130 is available for writing data. At operation 406, the media operations manager 142 selectively applies boundary WL offset values to read one or more WLs of the portion of the memory device 130 in addition to applying inner WL offset values in response to determining whether the portion of the memory device 130 is available for writing data.

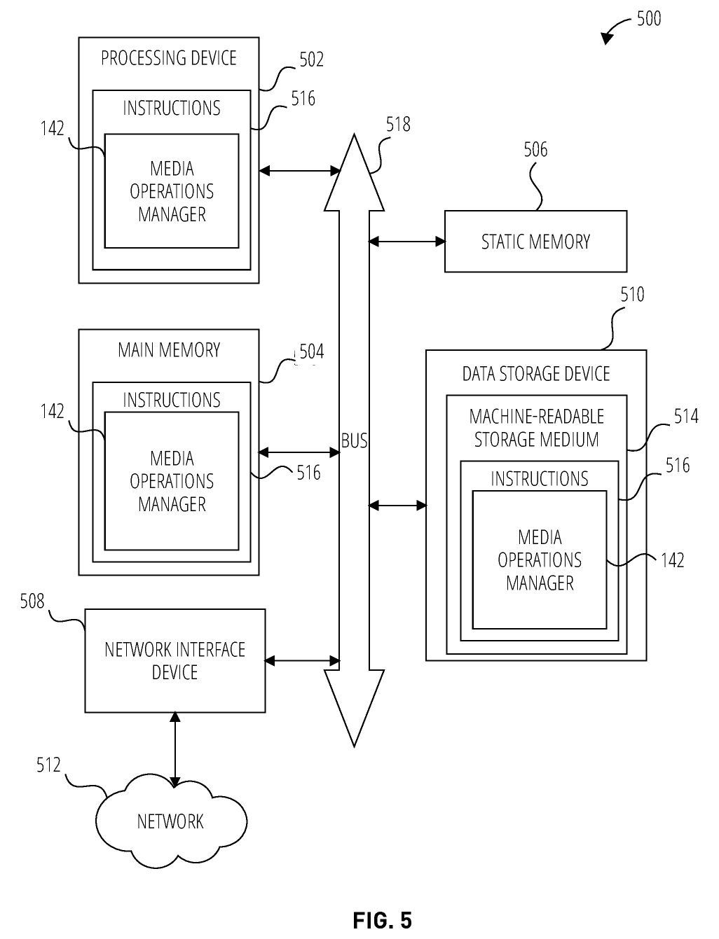

FIG. 5 illustrates an example machine in the form of a computer system 500 within which a set of instructions can be executed for causing the machine to perform any one or more of the methodologies discussed herein. In some examples, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage device 510, which communicate with each other via a bus 518.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an application-specific integrated circuit (ASIC), a field programmable gate array (FPGA), a digital signal processor (DSP), a network processor, or the like. The processing device 502 is configured to execute instructions 516 for performing the operations and steps discussed herein. The computer system 500 can further include a network interface device 508 to communicate over a network 512.

The data storage device 510 can include a machine-readable storage medium 514 (also known as a computer-readable medium) on which is stored one or more sets of instructions 516 or software embodying any one or more of the methodologies or functions described herein. The instructions 516 can also reside, completely or at least partially, within the main memory 504 and/or within the processing device 502 during execution thereof by the computer system 500, the main memory 504 and the processing device 502 also constituting machine-readable storage media. The machine-readable storage medium 514, data storage device 510, and/or main memory 504 can correspond to the memory sub-system 110 of FIG. 1.

In one example, the instructions 516 include instructions to implement functionality corresponding to providing block failure protection for a zone memory sub-system as described herein. While the machine-readable storage medium 514 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1: A system comprising: a memory device; and a processing device, operatively coupled to the memory device, configured to perform operations comprising: receiving a request to read data from a portion of the memory device; in response to receiving the request to read the data, determining whether the portion of the memory device is available for writing data; and selectively applying boundary word line (WL) offset values to read one or more WLs of the portion of the memory device in addition to applying inner WL offset values in response to determining whether the portion of the memory device is available for writing data.

Example 2. The system of Example 1, the operations comprising: in response to determining the portion is available for writing data, applying the inner WL offset values without boundary WL offset values to read one or more WLs of the portion of the memory device; and in response to determining the portion is unavailable for writing data, applying both inner WL offset values and boundary WL offset values to read the one or more WLs of the portion of the memory device.

Example 3. The system of any one of Examples 1-2, wherein the portion is determined to be available for writing data in response to determining that the portion comprises an open memory block, wherein the portion is determined to be unavailable for writing data in response to determining that the portion comprises a closed memory block.

Example 4. The system of Example 3, the operations comprising: accessing tracking information in response to receiving the request, the tracking information indicating whether the portion is available or unavailable for writing the data; and reading data from the portion of the memory device using at least one of the inner WL offset values or the boundary WL offset values.

Example 5. The system of Example 4, the operations comprising: reading the data using both the inner WL offset values and the boundary WL offset values in response to determining that the portion comprises the closed memory block.

Example 6. The system of Example 5, wherein the closed memory block is a partially programmed block (PB).

Example 7. The system of Example 6, wherein the PB transitions from being an open memory block to being a closed memory block in response to determining that a time period during which the open block has remained open exceeds a predetermined threshold.

Example 8. The system of any one of Examples 4-7, the operations comprising: reading the data using only the inner WL offset values in response to determining that the portion comprises the open memory block.

Example 9. The system of any one of Examples 1-8, wherein the portion comprises a plurality of WLs, the plurality of WLs comprising one or more inner WLs including an individual WL and a boundary WL, wherein the inner WL offset values are retrieved from an inner WL offset table, and wherein the boundary WL offset values are retrieved from a boundary WL offset table.

Example 10. The system of Example 9, the operations comprising: storing the inner WL offset table comprising a first plurality of read level offsets; and storing the boundary WL offset table comprising a second plurality of read level offsets, the boundary WL offset table representing a set of read level offsets for reading data from one or more WLs of a partially programmed block (PB) that has been closed and is unavailable for writing new data.

Example 11. The system of Example 10, the operations comprising: reading a first set of data from the one or more inner WLs of the portion using a first read level offset retrieved from the inner WL offset table; and reading a second set of data from the boundary WL of the portion using a combined read level offset generated based on the first read level offset and a second read level offset retrieved from the boundary WL offset table.

Example 12. The system of Example 11, the operations comprising: adding the first read level offset and the second read level offset to generate the combined read level offset.

Example 13. The system of any one of Examples 11-12, the operations comprising: retrieving a read threshold voltage for reading data from the portion; modifying the read threshold voltage by the first read level offset to read the first set of data; and modifying the read threshold voltage by the combined read level offset to read the second set of data.

Example 14. The system of any one of Examples 10-13, wherein the inner WL offset table associates a first WL group (WLG) with a first set of read level offsets corresponding to different levels of tri-level cell (TLC) storage, wherein the inner WL offset table associates a second WLG with a second set of read level offsets corresponding to the different levels of the TLC storage, wherein the boundary WL offset table associates the first WLG with a third set of read level offsets corresponding to the different levels of the TLC storage, and wherein the boundary WL offset table associates the second WLG with a fourth set of read level offsets corresponding to the different levels of the TLC storage.

Example 15. The system of any one of Examples 1-14, wherein determining whether the portion of the memory device is available for writing data comprises accessing a cursor that tracks writing progress within the portion.

Example 16. The system of any one of Examples 1-15, wherein the memory device comprises a three-dimensional (3D) NAND device.

Example 17. At least one non-transitory machine-readable storage medium comprising instructions that, when executed by a processing device, cause the processing device to perform operations comprising: receiving a request to read data from a portion of a memory device; in response to receiving the request to read the data, determining whether the portion of the memory device is available for writing data; and selectively applying boundary word line (WL) offset values to read one or more WLs of the portion of the memory device in addition to applying inner WL offset values in response to determining whether the portion of the memory device is available for writing data.

Example 18. A method comprising: receiving a request to read data from a portion of a memory device; in response to receiving the request to read the data, determining whether the portion of the memory device is available for writing data; and selectively applying boundary word line (WL) offset values to read one or more WLs of the portion of the memory device in addition to applying inner WL offset values in response to determining whether the portion of the memory device is available for writing data.

Example 19. The method of Example 18, wherein the portion is determined to be available for writing data in response to determining that the portion comprises an open memory block, wherein the portion is determined to be unavailable for writing data in response to determining that the portion comprises a closed memory block.

Example 20. The method of Example 19, comprising: in response to determining the portion is available for writing data, applying the inner WL offset values without boundary WL offset values to read one or more WLs of the portion of the memory device; and in response to determining the portion is unavailable for writing data, applying both inner WL offset values and boundary WL offset values to read the one or more WLs of the portion of the memory device.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

"Slow charge loss (SCL)" refers to charge retention loss or data retention loss that occurs in flash memory cells over time. SCL refers to the gradual leakage of electrical charge from the floating gate of a NAND cell, which can lead to data corruption or loss if left unchecked. This SCL is a natural aging process in flash memory and becomes more pronounced as the memory cells undergo more program/erase cycles and as the manufacturing process shrinks to smaller geometries. The rate of charge loss can be affected by factors such as temperature, the quality of the insulating oxide layer, and the overall design of the memory cell.

"Partially programmed block (PB)" refers to memory blocks that are not fully programmed and remain open with one or more sub-blocks that are empty and ready to be programmed. This is in contrast to full blocks (FBs) which are memory blocks that are fully programmed and closed. PBs require special handling for read operations, including the application of different read level offsets for inner word lines (WLs) and boundary WLs to reduce read disturb errors and other extrinsic defect related errors when reading data from these blocks.

"Inner WL" refers to any WL in a PB that does not contain the last programmed page. Inner WLs may require specific read level offsets retrieved from an inner WL offset table to reduce read disturb errors and other extrinsic defect related errors when reading data.

"Boundary WL" refers to the WL in a PB that contains the last programmed page. Boundary WLs may require special handling during read operations where both the inner WL offset and a modified boundary WL offset are combined to generate the read level offset used to read data, in order to reduce RBER associated with reading the last programmed portion.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device; and
a processing device, operatively coupled to the memory device, configured to perform operations comprising:
receiving a request to read data from a portion of the memory device;
in response to receiving the request to read the data, determining whether the portion of the memory device is available for writing data; and
selectively applying boundary word line (WL) offset values to read one or more WLs of the portion of the memory device in addition to applying inner WL offset values in response to determining whether the portion of the memory device is available for writing data.

2. The system of claim 1, the operations comprising:
in response to determining the portion is available for writing data, applying the inner WL offset values without boundary WL offset values to read one or more WLs of the portion of the memory device; and
in response to determining the portion is unavailable for writing data, applying both inner WL offset values and boundary WL offset values to read the one or more WLs of the portion of the memory device.

3. The system of claim 1, wherein the portion is determined to be available for writing data in response to determining that the portion comprises an open memory block, wherein the portion is determined to be unavailable for writing data in response to determining that the portion comprises a closed memory block.

4. The system of claim 3, the operations comprising:
accessing tracking information in response to receiving the request, the tracking information indicating whether the portion is available or unavailable for writing the data; and
reading data from the portion of the memory device using at least one of the inner WL offset values or the boundary WL offset values.

5. The system of claim 4, the operations comprising:
reading the data using both the inner WL offset values and the boundary WL offset values in response to determining that the portion comprises the closed memory block.

6. The system of claim 5, wherein the closed memory block is a partially programmed block (PB).

7. The system of claim 6, wherein the PB transitions from being an open memory block to being a closed memory block in response to determining that a time period during which the open block has remained open exceeds a predetermined threshold.

8. The system of claim 4, the operations comprising:
reading the data using only the inner WL offset values in response to determining that the portion comprises the open memory block.

9. The system of claim 1, wherein the portion comprises a plurality of WLs, the plurality of WLs comprising one or more inner WLs including an individual WL and a boundary WL, wherein the inner WL offset values are retrieved from an inner WL offset table, and wherein the boundary WL offset values are retrieved from a boundary WL offset table.

10. The system of claim 9, the operations comprising:
storing the inner WL offset table comprising a first plurality of read level offsets; and
storing the boundary WL offset table comprising a second plurality of read level offsets, the boundary WL offset table representing a set of read level offsets for reading data from one or more WLs of a partially programmed block (PB) that has been closed and is unavailable for writing new data.

11. The system of claim 10, the operations comprising:
reading a first set of data from the one or more inner WLs of the portion using a first read level offset retrieved from the inner WL offset table; and
reading a second set of data from the boundary WL of the portion using a combined read level offset generated based on the first read level offset and a second read level offset retrieved from the boundary WL offset table.

12. The system of claim 11, the operations comprising:
adding the first read level offset and the second read level offset to generate the combined read level offset.

13. The system of claim 11, the operations comprising:
retrieving a read threshold voltage for reading data from the portion;
modifying the read threshold voltage by the first read level offset to read the first set of data; and
modifying the read threshold voltage by the combined read level offset to read the second set of data.

14. The system of claim 10, wherein the inner WL offset table associates a first WL group (WLG) with a first set of read level offsets corresponding to different levels of tri-level cell (TLC) storage, wherein the inner WL offset table associates a second WLG with a second set of read level offsets corresponding to the different levels of the TLC storage, wherein the boundary WL offset table associates the first WLG with a third set of read level offsets corresponding to the different levels of the TLC storage, and wherein the boundary WL offset table associates the second WLG with a fourth set of read level offsets corresponding to the different levels of the TLC storage.

15. The system of claim 1, wherein determining whether the portion of the memory device is available for writing data comprises accessing a cursor that tracks writing progress within the portion.

16. The system of claim 1, wherein the memory device comprises a three-dimensional (3D) NAND device.

17. At least one non-transitory machine-readable storage medium comprising instructions that, when executed by a processing device, cause the processing device to perform operations comprising:
receiving a request to read data from a portion of a memory device;
in response to receiving the request to read the data, determining whether the portion of the memory device is available for writing data; and
selectively applying boundary word line (WL) offset values to read one or more WLs of the portion of the memory device in addition to applying inner WL offset values in response to determining whether the portion of the memory device is available for writing data.

18. A method comprising:
receiving a request to read data from a portion of a memory device;
in response to receiving the request to read the data, determining whether the portion of the memory device is available for writing data; and
selectively applying boundary word line (WL) offset values to read one or more WLs of the portion of the memory device in addition to applying inner WL offset values in response to determining whether the portion of the memory device is available for writing data.

19. The method of claim 18, wherein the portion is determined to be available for writing data in response to determining that the portion comprises an open memory block, wherein the portion is determined to be unavailable for writing data in response to determining that the portion comprises a closed memory block.

20. The method of claim 19, comprising:
in response to determining the portion is available for writing data, applying the inner WL offset values without boundary WL offset values to read one or more WLs of the portion of the memory device; and
in response to determining the portion is unavailable for writing data, applying both inner WL offset values and boundary WL offset values to read the one or more WLs of the portion of the memory device.
